(19) United States
(12) Patent Application Publication
(10) Pub. No.: US 2026/0020356 A1
(43) Pub. Date: Jan. 15, 2026

(54) OPTICALLY QUENCHABLE CARBON-DOPED GALLIUM NITRIDE PHOTOCONDUCTIVE SEMICONDUCTOR SWITCHES

(71) Applicant: Lawrence Livermore National Security, LLC, Livermore, CA (US)

(72) Inventors: Qinghui Shao, Fremont, CA (US); Lars F. Voss, Livermore, CA (US)

(21) Appl. No.: 18/770,536

(22) Filed: Jul. 11, 2024

(51) Int. Cl. H01L 31/11; H01L 31/0224; H01L 31/0232; H01L 31/0304; H01L 31/16; H01S 5/30; H01S 5/343

(52) U.S. Cl. CPC H10F 30/245; H01S 5/3013; H01S 5/34333; H10F 55/26; H10F 77/1243; H10F 77/1246; H10F 77/244; H10F 77/496

(57) ABSTRACT

Devices, systems and methods for operating and using an optically quenchable carbon-doped gallium nitride photoconductive semiconductor switch (PCSS) are described. An example method includes illuminating a carbon-doped gallium nitride material of the photoconductive semiconductor switch with a first laser light within a first range of wavelengths to trigger the photoconductive semiconductor switch to a conductive state, turning off or blocking the first laser light, and illuminating the carbon-doped gallium nitride material with a second laser light within a second range of wavelengths to trigger the photoconductive semiconductor switch to an insulating state. In this example, the first range of wavelengths comprises an ultraviolet (UV) or a blue wavelength range, the second range of wavelengths comprises an infrared (IR) or a red wavelength range, and switching from the conductive state to the insulating state occurs within a sub-nanosecond range.

### STATEMENT REGARDING FEDERALLY SPONSORED RESEARCH OR DEVELOPMENT

This invention was made with Government support under Contract No. DE-AC52-07NA27344 awarded by the United States Department of Energy. The Government has certain rights in the invention.

### TECHNICAL FIELD

This patent document is directed generally to a photoconductive semiconductor switch, and more particularly, to operating and using a carbon-doped gallium nitride (GaN:C) photoconductive semiconductor switch (PCSS).

### BACKGROUND

Photoconductive semiconductor switches (or switching devices) are integral to modern power electronics converters, and are used or in consideration for several high-power applications where traditional electronic devices cannot meet requirements for speed, power, or electromagnetic isolation from drive components. However, traditional photoconductive semiconductor switch architectures have been unable to meet emerging requirements for exceptionally fast turn-off times and supporting much larger ranges of pulsed power, radio frequencies, and power electronics applications.

### SUMMARY

Embodiments of the disclosed technology relate to methods, devices and systems for operating and using a carbon-doped gallium nitride (GaN:C) photoconductive semiconductor switch (PCSS). The disclosed embodiments can be used for several high power applications where traditional electronic devices cannot meet requirements for speed, power, or electromagnetic isolation from drive components.

The disclosed embodiments include a device and method for operating and using a GaN:C PCSS. In an example aspect, a method for operating a photoconductive semiconductor switch includes illuminating a carbon-doped gallium nitride material of the photoconductive semiconductor switch with a first laser light within a first range of wavelengths to trigger the photoconductive semiconductor switch to a conductive state, turning off or blocking the first laser light, and illuminating the carbon-doped gallium nitride material with a second laser light within a second range of wavelengths to trigger the photoconductive semiconductor switch to an insulating state. In this example, the first range of wavelengths comprises an ultraviolet (UV) or a blue wavelength range, and the second range of wavelengths comprises an infrared (IR) or a red wavelength range. Herein, switching from the conductive state to the insulating state occurs within a sub-nanosecond range, and the photoconductive semiconductor switch is operable to remain in the insulating state for one or more seconds as long as the carbon-doped gallium nitride material is not illuminated with the first laser light.

In another example aspect, a device includes one or more electrodes configured to receive one or more voltages, and a region comprising a GaN:C material that is configured to (a) receive a first laser light within a first range of wavelengths comprising a UV wavelength or a blue wavelength to trigger the device to a conductive state, and (b) receive a second laser light within a second range of wavelengths comprising an IR wavelength or a red wavelength, while the first laser light is turned off or otherwise blocked, to trigger the device to an insulating state.

### BRIEF DESCRIPTION OF THE DRAWINGS

FIG. 1 illustrates an example of carbon-doped gallium nitride (GaN:C) with three defects or impurity levels.

FIG. 2 illustrates a plot comparing the measured and simulated normalized transient scope voltage when the photoconductive semiconductor switch (PCSS) is illuminated with a 380 nm laser.

FIG. 3 illustrates a plot comparing the measured and simulated normalized transient scope voltage when the PCSS is illuminated with a 380 nm laser and then with a 1064 nm laser.

FIG. 4 illustrates an example of a optically triggered GaN:C thyristor.

FIG. 5 illustrates an example of a GaN:C PCSS with integrated ultraviolet (UV) and infrared (IR) emitters.

FIG. 6A illustrates an example of the GaN:C PCSS as an opening switch.

FIGS. 6B and 6C illustrate a time-series of the current and voltage associated with the GaN:C PCSS as an opening switch, as shown in FIG. 6A, respectively.

FIG. 7 illustrates an example of a simplified optical transition and recombination model for the GaN:C PCSS.

FIGS. 8A-8C illustrate time-series plots of the normalized voltage of a GaN:C PCSS illuminated with a 380 nm laser and then with a 1064 nm laser.

FIG. 9 illustrates the tuning of excitation bands for example processes directed to photo-activated n-type conductivity and quenching.

FIG. 10 illustrates the tuning of excitation bands for example processes directed to photo-activated p-type conductivity and quenching.

FIG. 11 illustrates an example of a conversion layer, directly on top of the GaN:C layer, that converts a first wavelength to a desired longer wavelength.

FIG. 12 illustrates an example of a optical bipolar junction transistor (OBJT) based on carbon-doped gallium nitride (GaN:C).

FIGS. 13A-13C illustrate band diagrams of the oBJT, illustrated in FIG. 12, in the OFF state, illuminated with a blue laser, and illuminated with an IR laser, respectively.

FIGS. 14A and 14B illustrate time-series plots of the transient photocurrent for the oBJT illustrated in FIG. 12, in the linear and log scales, respectively.

FIG. 15 illustrates a flowchart of an example method for operating a GaN:C PCSS.

FIG. 16 illustrates an example of an apparatus that can implement methods and techniques for operating and using a GaN:C PCSS.

### DETAILED DESCRIPTION

A photoconductive semiconductor switch (PCSS) is an electrical switch which is based on the photoconductivity of a material, i.e., an increase in its electrical conductance as a consequence of irradiation with light. Photoconductive switches typically use a semiconductor material, in which the absorbed light (with a photon energy above the band gap energy) generates free carriers, which then contribute to the conductivity.

Most PCSS are either ‘high-gain’ or ‘linear’, with high-gain devices using a small laser pulse and triggering conductivity through avalanche or current filamentation processes, but lacking fine control of the output waveform. Linear mode PCSS conductivity is directly proportional to input laser energy, with switching speed and photoresponsivity being inversely correlated. A third type, known as the bulk optical semiconductor switch (BOSS), was investigated in the late 1980s and early 1990s. This BOSS device, made of gallium arsenide

(GaAs) with both silicon (Si) and copper (Cu) doping, was capable of being triggered into the conducting state with a short wavelength laser pulse and triggered into the insulating state with a long wavelength laser pulse. Ultimately, the performance was limited due to the relatively poor on: off ratio, as well as the poor quality of GaAs for most high-power devices. More recently, a new type of BOSS made of gallium nitride (GaN) doped with carbon (C) is being used, which possesses exceptional resistivity (>1e13 ohm-cm) as well as responsivity to below band gap but short wavelength illumination (>2 A-cm/W-kV), but is unsuited for many applications due to exceptional carrier lifetime (milliseconds) which results in very slow turn-off and switching capability limited to 10's of Hz.

Currently, silicon (Si) insulated gate bipolar junction transistors (IGBTs) dominate in most high-power applications but cannot satisfy the increasing demand of operating at higher temperature, higher blocking voltage, and higher switching frequency. Wide-bandgap (WBG) semiconductors have the potential to meet these requirements due to their inherent electrical properties but suffer from material defects and short carrier lifetimes, which limits the voltage rating, and increases on-state loss. The electrical performances of 3-terminal power switches with controlled turn-on and -off characteristics are compared in Table 1.

TABLE 1
Comparison of 3-terminal power switches with controlled turn-on and -off characteristics

| | | | SiC | | GaN | | Diamond | | GaN:C PCSS | | Quenchable | |
|---|---|---|---|---|---|---|---|---|---|---|---|---|
| Technology | Si IGBT | | MOSFET | | HEMT | | PCSS | | (DOD) | | GaN:C | |
| Voltage rating | 6.5 | kV | 15 | kV | 650 | V | >15 | kV | >15 | kV | >15 | kV |
| Current rating | 750 | A | 100 | A | <100 | A | 500 | A | 500 | A | 500 | A |
| Switching frequency | 5 | kHz | 50 | kHz | 1 | MHz | >10 | GHz | <30 | Hz | >100 | MHz |

| | | | | | | | | | |
|---|---|---|---|---|---|---|---|---|---|
| Optical power | N/A | N/A | N/A | >10 | kW | ~5 | W | ~5 | W |

As seen therein, compared to Si, SiC has a higher blocking voltage and about 10x faster switching speed. GaN has an even higher critical field and higher electron saturation velocity, which increase the frequency to MHz, but it is with a very short carrier lifetime (several to tens of nanoseconds) due to direct bandgap which makes it nearly impractical for making a high-quality high-power switch, like thyristor. An alternative to building switches is to use photons to excite carriers, e.g., in the form of an SiC, GaN, and/or diamond photoconductive semiconductor switch (PCSS). These devices are typically used for high-power radio frequencies, where they can achieve GHz or greater operation at exceptional power levels. However, increasing frequency capability comes with a 1:1 increase in laser power requirement, which makes these devices unsuitable for broader use where GHz speeds are not required.

As discussed above, the carbon-doped GaN has exceptional photo-responsivity, three to four orders of magnitude higher than diamond used for PCSS, due to its long carrier lifetime (1-10 ms), opening the way to the use of semiconductor laser diodes which can output 1-10 W. However, this limits the demonstrated switching speed to on the order of 10-20 Hz.

The disclosed technology overcomes above-discussed drawbacks and provides additional features and benefits, including a method for operating carbon-doped gallium nitride (GaN:C) in the BOSS mode, enabling exceptionally fast turn-off time and making the GaN:C device suitable for a much larger range of pulsed power, radiofrequency, and power electronics applications. It is noted that these benefits are not achievable with other GaN or SiC technologies, and offer the chance to increase voltage into the 10's of kV per device while increasing switching speed compared to state-of-the-art power devices. The described embodiments enable the possibility of a pulsed power circuit with fully integrated GaN:C based active components for timing many stages together by use of the same optical system, and supporting applications requiring fast switching for improved control and higher power density integration. Combined with benefits of optical triggering for high-power systems, low jitter and high tolerance to electromagnetic interference, the described GaN:C based power switches are suited for operations with fast response time and low conduction/switching loss (e.g., for use in future power grids).

In some embodiments, the carbon-doped GaN layer is grown (e.g., using hydride vapor phase epitaxy) on a highly conductive n-type GaN substrate with a nominal layer thickness of 100 μm. The photoconductive switch based on GaN:C has a device size of 2 mm in diameter. In an example, a pulsed 380 nm laser and pulsed 1064 nm laser were used to test the device's photo-response. The results showed a very long carrier lifetime in a range of milliseconds under 380 nm illumination, and very short lifetime in a range of sub-nanoseconds under 1064 nm illumination. The unique photo-responsive characteristics are due to the huge difference between electron and hole capture cross-sections of carbon sites in GaN (and analogous to GaAs BOSS with Cu doping). The electrons from shallow donors, e.g., silicon or nitrogen vacancies are captured by carbon sites, deep acceptor traps in GaN, to ensure semi-insulating property. The trapped electrons are excited to the conduction band under 380 nm illumination and make the device conductive. Because of the very small electron capture cross-section, the free electrons last for long time before they are captured back by the traps. The conductivity can be quenched quickly by illuminating the device with a 1064 nm laser. The holes in carbon sites are excited into the valence band, and quickly recombine with electrons via radiative or effective nonradiative recombination and make the device resistive. Such photo-responsive characteristics enable GaN:C a strong contender semiconductor in power electronics applications with high voltage blocking and superfast switching speed.

There are at least 2 energies required for the excitation and quenching process that are dependent on the position of the defect energy levels relative to the conduction and valence band positions. To tune the excitation and quenching energies independently for a given defect level, the electronic structure of the host material can be tuned via alloying and/or strain to more favorably align the photoexcitation energies to standard light source wavelengths, such as those commercially available in laser or light-emitting diodes. For example, the valence band and conduction positions in gallium nitride (GaN) can be modified through the incorporation of different amounts of other group-III elements like Al (which lowers the relative valence band position and increases the relative conduction band position on an absolute energy scale), and/or In (which lowers the relative conduction band position and increases the relative valence band position on an absolute energy scale). Similarly, strain (such as compressive or tensile stress arising from epitaxial mismatches) can also tune the absolute and relative energetic positioning of valence bands and conduction bands that participate in the excitation and quenching processes, although the energetic modifications are typically far smaller than from alloying. The use of these approaches at modifying the underlying host electronic structure allows for largely independent tuning of the wavelengths underpinning 1) the photoconductive excitation and 2) the quenching excitation. This results in an improvement of the excitation efficiencies associated with activating and quenching photoconductivity with readily obtainable light sources with sufficiently high power and reliability that can ensure robust PCSS devices.

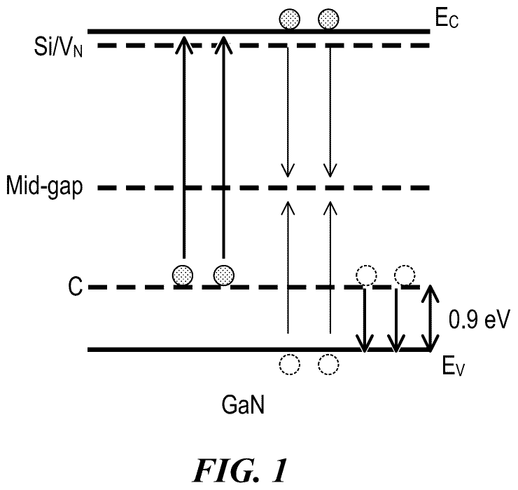

In some embodiments, and as illustrated in FIG. 1, a physical model with 3 defect levels is used to determine carrier dynamics inside the device. Herein, the defect or impurity levels involved are:
1. shallow donor levels, e.g., silicon or nitrogen vacancies,
2. deep acceptor levels from carbon (0.9 eV above the valence band), and
3. mid-gap levels for effective carrier recombination.

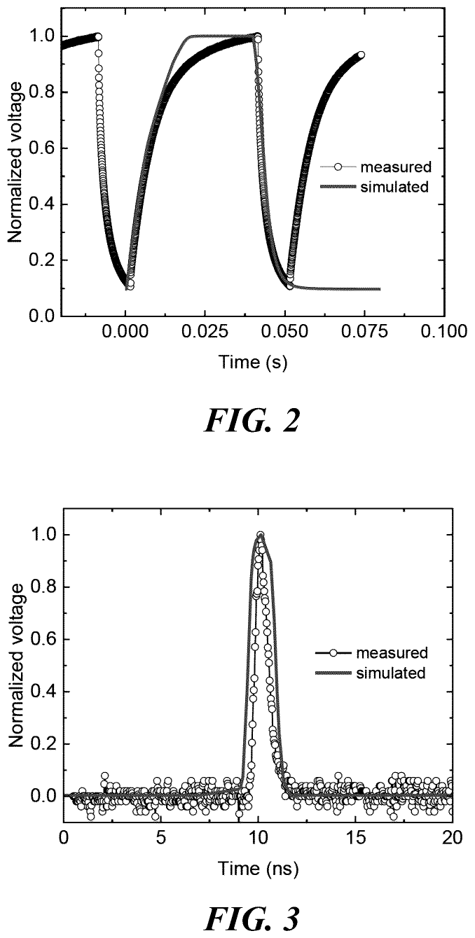

The simulated results for this physical model are plotted together with measurements in FIGS. 2 and 3 for comparison. For FIG. 2, the measured data was generated by testing the 380 nm photo response at a bias of 200 V and a laser diode driven by a function generator at 20 Hz and 80% duty cycle. The normalized transient scope voltage with a 50Ω load (black circles) and the simulation results (solid line) are illustrated in FIG. 2. The rise-time (20%-80%) is 10.3 msec and fall time (20%-80%) is 5.3 msec. The rise time is strongly dependent on the laser intensity, and fall time is primarily determined by the electron capture cross-section. In the simulations, an electron capture cross-section of 2×10⁻²¹ cm² and a hole capture cross-section of 2×10⁻¹⁴ cm² were initially selected. As shown in FIG. 2, a portion of the voltages of the rising edge (0.1-0.8) and the voltages of the falling edge (0.9-0.1) match well with the measured scope voltage. The discrepancies in the portion of the rising edge (0.8-1) may be due to variance of trap densities, the device capacitance, the instability of the laser diode, etc.

FIG. 3 compares measurements and simulations for conductivity quenching, with the experiments being conducted by biasing the device at 200 V, and illuminating the device with a continuous wave (CW) 380 nm laser and a pulsed 1064 nm laser with 0.7 ns full width at half maximum (FWHM). The normalized scope voltage with the 5002 load (black circles) and the simulation results (solid line) are illustrated in FIG. 3. The FWHM of measured data is 0.74 ns, indicating the hole recombination/capture rate is in the range of sub-nanoseconds or even faster. The simulated FWHM is 1.4 ns, which suggests the hole capture cross-section would be bigger or mid-gap density would be higher than the simulation configuration.

In some embodiments, to fully quench the free electrons, an ideal 1064 nm laser power can be used for generating the same number of holes. An advantage of the large hole capture cross-section is that an overshooting 1064 nm laser will generate more than enough holes to recombine with electrons, and extra holes will be quickly captured back to carbon sites. This advantageously ensures a fast switching off process with an unmatched IR laser source.

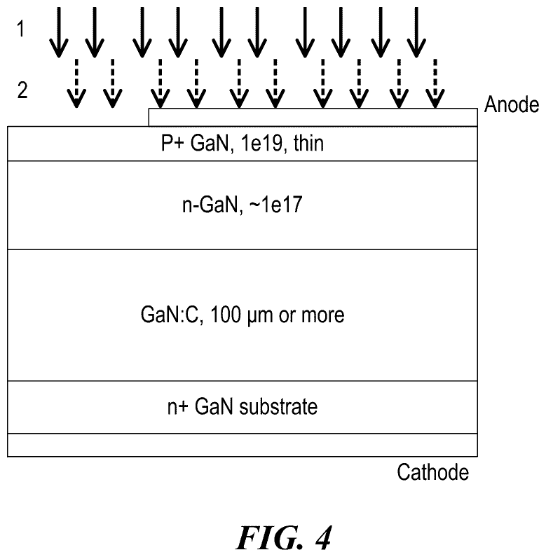

Embodiments of the disclosed technology include an optically-triggered GaN:C thyristor (a four-layer semiconductor device consisting of alternating p-type and n-type materials). As illustrated in FIG. 4, this embodiment includes a first layer of p-type GaN with a dopant concentration of about 1×10¹⁹ cm⁻³ below an anode, a second layer of n-GaN (beneath the first layer) with a dopant concentration of about 1×10¹⁷ cm⁻³, a third layer of the carbon-doped gallium nitride (GaN:C) material, and a fourth layer that is an n-type GaN substrate, which is positioned above the cathode. Herein, a thickness the p-type GaN (first) layer of the thyristor is less than the thickness of any of the other layers, and the thickness of the third layer of the GaN:C material is about 100 μm or more. Furthermore, the (carbon) dopant concentration is about 1×10¹⁸ cm⁻³.

In some embodiments, the GaN:C thyristor can be triggered to an OFF (or blocking) state by performing the following operations:
1. Set the anode with high positive voltage relative to cathode.
2. Turn on the red or infrared (IR) beam, thereby exciting holes from deep acceptors (the carbon site) to make the GaN:C p-type. This results in a major voltage drop across the n-GaN/GaN:C junction (e.g., reverse biased). Alternatively, if there is no IR beam, holes and electrons can be injected into the GaN:C layer to make it conductive.
3. Turn off the IR beam, and the device remains in the blocking state.

In some embodiments, the GaN:C thyristor can be triggered to an ON (or conductive) state by performing the following operations:
1. Turn on the blue or ultraviolet (UV) beam 2, thereby exciting electrons to make GaN:C conductive (n-type). Herein, the P+/N junction is forward biased with low resistivity.
2. Turn off the blue beam. However, high conductance is maintained for long time (˜ms) due to the small capture cross-section of electrons in GaN:C.

In some embodiments, the IR beam can be turned back on in order to return the GaN:C to its OFF (or insulating/blocking) state. Once the conductive current is ceased, the IR beam can be turned off.

In the above-described embodiments, the pulsed laser (red/IR and blue/UV) are only needed during transitions. The majority of the duration in the ON and OFF state are maintained without the laser being used.

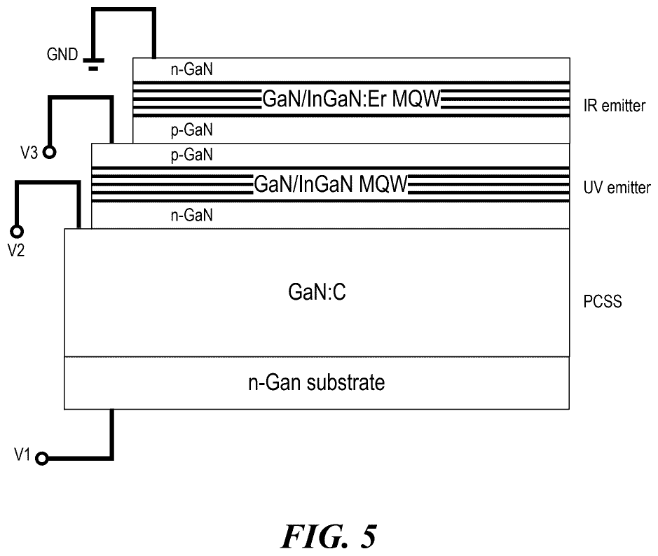

Embodiments of the disclosed technology include a PCSS with integrated UV and IR emitters, as shown in FIG. 5, which require no external lasers for operation. As shown in FIG. 5, this embodiment includes a layer of the carbon-doped gallium nitride (GaN:C) material, which is above an n-type GaN substrate, and the integrated IR emitter layer (on the top of the device) and the integrated UV emitter layer. Herein, the IR emitter is grounded, and the UV emitter, the layer of GaN:C material, and the n-type GaN substrate are set to V3, V2, and V1, respectively.

In some embodiments, each of the IR and UV emitters consists of a layer with a multiple quantum well (MQW) structure that is positioned in between p-type and n-type GaN layers. Herein, the MQW structure consists of alternating thin layers of two semiconductor materials. In some examples, the IR emitter uses a GaN material and an erbium (Er)-doped indium gallium nitride (InGaN: Er) MQW structure and the UV emitter uses a GaN material and a InGaN MQW structure. In the example of the IR emitter, InGaN: Er can be replaced by InGaN with a high indium (In) composition. In these examples, the InGaN bandgap range spans 0.77-3.4 eV. In other embodiments, the MQW structures may not be needed, e.g., a single layer of GaN/InGaN: Er for the IR emitter or a single layer of GaN/InGaN for the UV emitter can be used instead of the MQW structure.

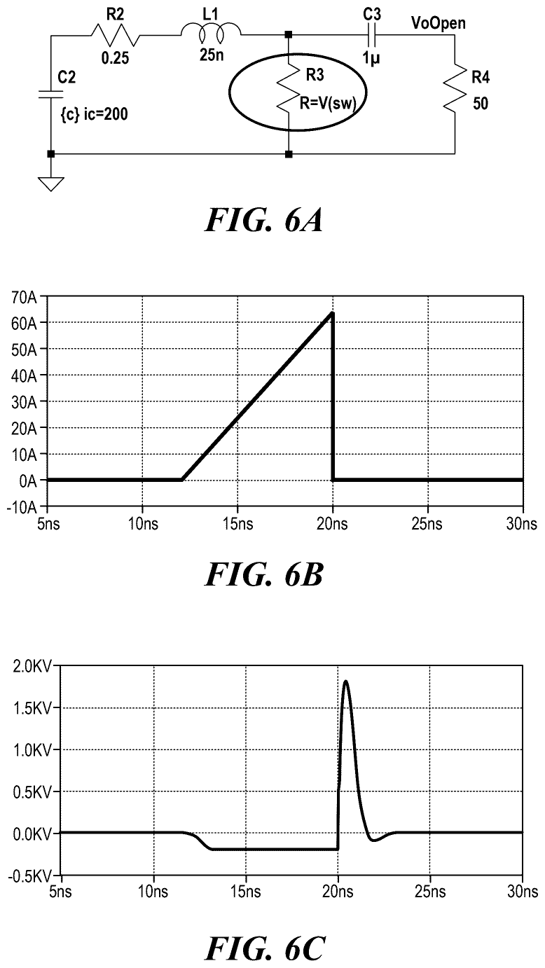

Embodiments of the disclosed technology include configuring the GaN:C PCSS as an opening switch, as illustrated in the circuit diagram in FIG. 6A, and with FIGS. 6A and 6B illustrating a time-series of the current and voltage associated with the GaN:C PCSS operating as an opening switch. As shown therein, the PCSS is in parallel with the load with the capacitor C3 blocking DC and being invisible to the pulse. The PCSS can be triggered ON, and is configured to shunt a closely coupled capacitance. Furthermore, inductor L1 and resistor R2 can be used to limit or tune the inrush current. When the conductivity of the PCSS is quenched, i.e., the PCSS in triggered to the OFF state, the output voltage is determined as:

$${V}_{out} \approx {L}_{1} \cdot di / dt .$$

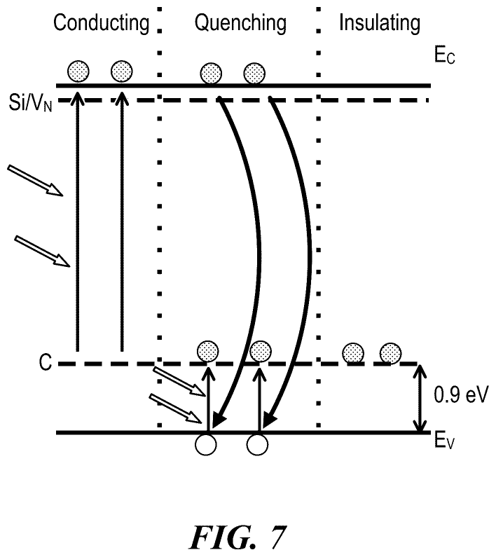

For the above-described embodiments, FIG. 7 illustrates an example of a simplified optical transition and recombination model for the GaN:C PCSS device. Carbon is a deep level acceptor in GaN, populated with electrons by donors such as silicon (Si). By using a wavelength between 370-410 nm, these electrons can be excited to make the GaN conductive. Because of the long lifetime, the electrons will take milliseconds to decay back to their original level. This process can be accelerated by using a second wavelength, optimally around 1000 nm-1200 nm, to repopulate the carbon level with electrons from the valence band, in the process creating a free hole. The recombination process of the electron and hole, by contrast, is exceptionally fast due to the direct bandgap of GaN, on the order of 500 ps.

As shown in FIG. 7, to trigger the device ON (denoted “conducting” in the figure), illuminating the device with a blue/UV laser (˜380 nm) excites the electrons to the conduction band. In order to trigger the device OFF (denoted “quenching” in the figure), the red/IR laser illuminates the device and excites holes to the valence band or electrons from the valence band to the carbon site, thereby causing the electrons to recombine with the holes. And the device remains in the OFF state (denoted “insulating” in the figure) as long as the blue/UV laser is not turned on again. Herein, there are no free electrons in the conduction band, and the excess holes are captured back to the carbon site.

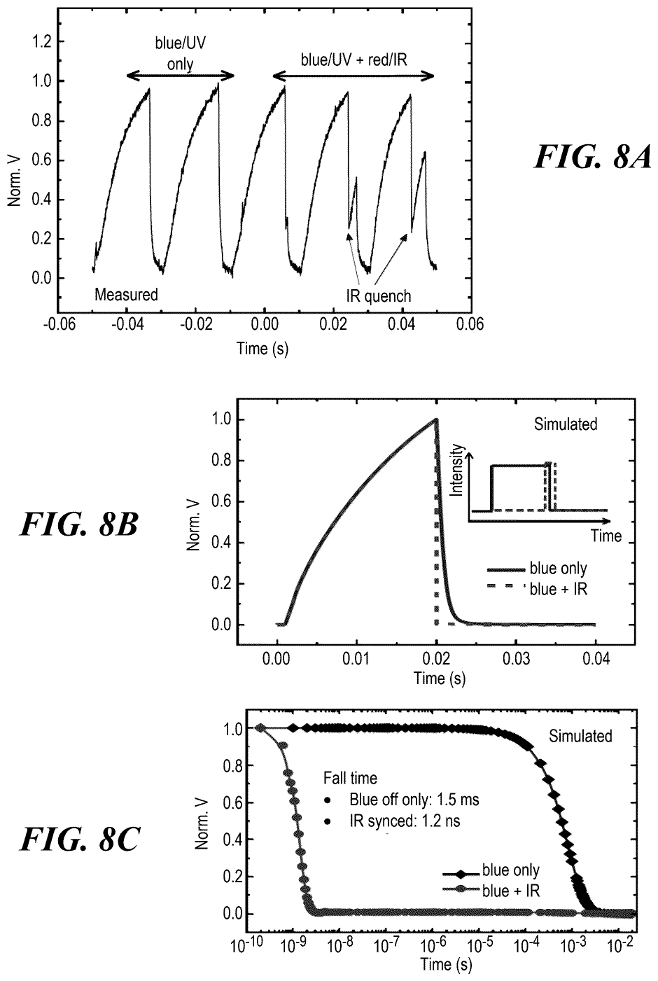

FIGS. 8A-8C illustrate time-series plots of the normalized voltage of a GaN:C PCSS illuminated with a 380 nm laser and then with a 1064 nm laser. FIG. 8A shows a pulse train measured on a GaN:C PCSS, with the first two pulses using only 380 nm light, and the final two pulses showing an IR pulse during the ON-cycle of the blue light, representing quenching. FIG. 8B shows simulated curves based on this data for the case of both blue and a synchronized blue triggering and IR quenching operation. FIG. 8C shows a zoomed-in of the turn off process, with the turn off time reduced from milliseconds to nanoseconds, which is the enabling advance to increasing the operational frequency from the low 10's of Hz up to 100's of MHz.

A summary of the rise and fall times for the measured and simulated GaN:C PCSS, for when only the blue/UV laser used and when both the blue/UV and red/IR lasers are used, is shown in Table 2. A rise time of 13 ms indicates a long electron carrier lifetime. Electrons are constantly generating during this process before being trapped back. In order to achieve a faster rise time, a pulsed blue/UV laser with much shorter pulse width (e.g., us) is used.

TABLE 2
Rise and fall times for measured and simulated GaN:C in conductive state

| | Measurement | Measurement w/IR | Simulation | Simulation w/IR (synced | |
|---|---|---|---|---|---|
| | w/o IR | (inside blue pulse) | w/o IR | to blue pulse edge) | |
| Rise time | 13.1 msec | 13.1 msec | 15.2 msec | 15.2 | msec |
| Fall time | 1.1 msec | 0.15 msec | 1.5 msec | 1.2 | ns |

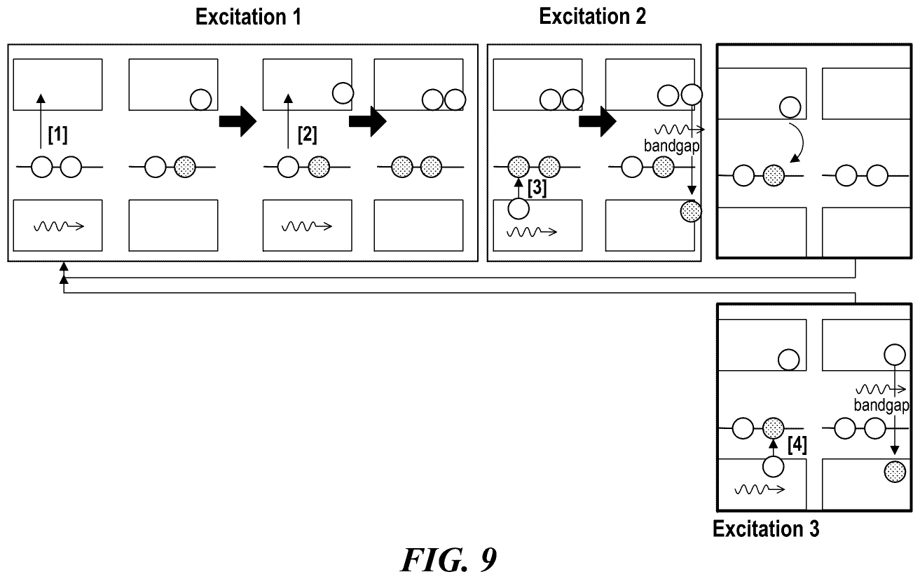

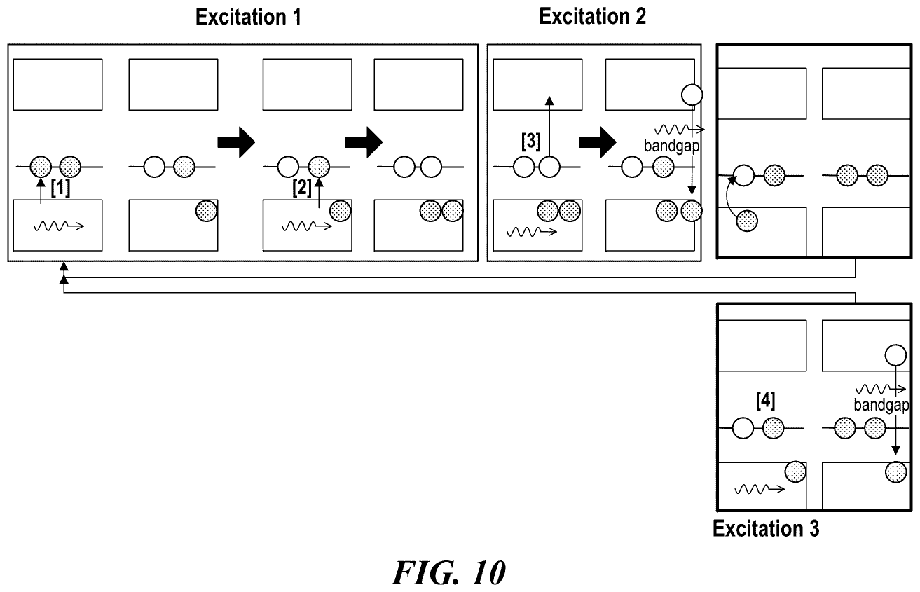

As discussed above, excitation and quenching energies can be tuned independently for a given defect level, as can the electronic structure of the host material. FIGS. 9 and 10 illustrate examples of tuning excitation bands for four example processes that include transitions [1] and [2] associated with conductivity and triggering the ON state, transition [3] associated with quenching and triggering the OFF state, and transition [4] associated with remaining in the insulating or blocking (or OFF) state.

FIG. 9 illustrates the tuning of excitation bands for example processes directed to photo-activated n-type conductivity and quenching. As shown therein, Excitation 1 wavelength is chosen to selectively excite transitions [1] and [2], yielding photo-activated n-type conductivity. In some examples, this can be achieved using multiple wavelengths to simultaneously drive transitions [1] and [2]. Excitation 2 wavelength is chosen to selectively excite transition [3] that quenches the photoconductivity generated by Excitation 1. Another Excitation 3 wavelength (transition [4]) may also be utilized to tune photo-response and transients of activated photoconductivity. Herein, electronic structure engineering (alloying, epitaxial strain/elastic modulation, and/or deformation) can selectively influence conduction band positions and excitation wavelengths for photoconduction transitions [1] and [2], and/or selectively influence the valence band positions and excitation wavelengths for quenching transitions [3] and [4].

Similarly, FIG. 10 illustrates the tuning of excitation bands for example processes directed to photo-activated p-type conductivity and quenching. As shown therein, Excitation 1 wavelength is chosen to selectively excite transitions [1] and [2], yielding photo-activated p-type conductivity. In some examples, this can be achieved using multiple wavelengths to simultaneously drive transitions [1] and [2]. Excitation 2 wavelength is chosen to selectively excite transition [3] that quenches the photoconductivity generated by Excitation 1. Another Excitation 3 wavelength (transition [4]) may also be utilized to tune photo-response and transients of activated photoconductivity. Herein, electronic structure engineering (alloying, epitaxial strain/elastic modulation, and/or deformation) can selectively influence valence band positions and excitation wavelengths for photoconduction transitions [1] and [2], and/or selectively influence the conduction band positions and excitation wavelengths for quenching transitions [3] and [4].

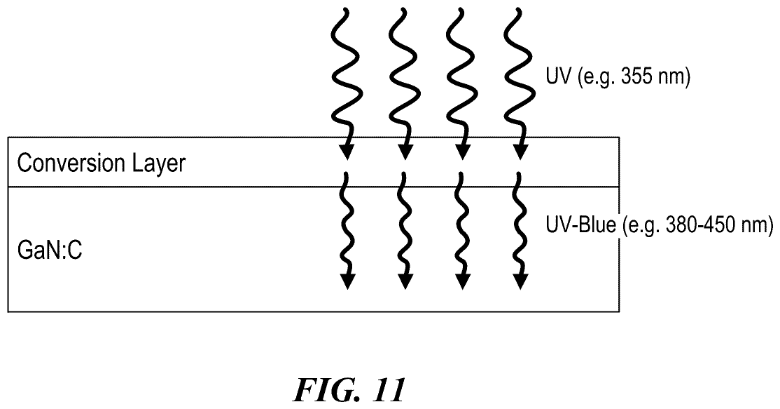

The described embodiments, which include GaN:C BOSS devices, need to be photo-activated at wavelengths around 380-450 nm. In order to use a standard Nd: YAG laser (or other long wavelength light source >450 nm), the wavelength needs to be converted to this wavelength range. This can be accomplished in two steps. A standard Nd: YAG laser will used as a prototypical example. First, the first harmonic (1064 nm) needs upconverted to at least the third harmonic (355 nm) and then this is downconverted to 380-450 nm. FIG. 11 illustrates an example of an integrated downconversion process. As shown therein, a conversion layer absorbs or partially absorbs UV at 355 nm and then emits light the longer desired wavelength, e.g. 380-450 nm. In this example architecture, an electrode can be placed above the conversion layer, between the conversion layer and the GaN:C layer, or on the GaN:C layer on either side of the conversion layer. While FIG. 11 depicts the conversion layer directly on the GaN:C, it could also be isolated as an independent component of a larger system.

In some embodiments, the conversion layer may include one or more of:
Bulk epitaxial semiconductor (e.g., InGaN, InAlGaN, InAlN, etc.)
Epitaxial semiconductor composed of quantum wells (e.g., GaN/InGaN, AlGaN/InGaN)
Epitaxial semiconductor composed of quantum dots (e.g., InGaN in AlGaN, InGaN in GaN)
Epitaxial semiconductor with a fluorescent dopant (e.g., GaN: Eu, AlGaN: Eu)
Luminescent layer, e.g., phosphor/fluorophore, quantum dots or nanoparticles (e.g. ZnO), and/or fluorescent dyes (e.g. laser dyes)

In the example described in FIG. 11, the starting source was a long wavelength that was upconverted. Here, a conversion layer would still be needed if the primary light source is short (<380 nm).

In some embodiments, a similar downconversion layer could also be used to downconvert the light to the longer wavelengths (450-2000 nm) needed to quench the device. For example, this step would be needed if the primary light source was a laser diode emitting at 532 or 355 nm.

Embodiments of the disclosed technology can be used in a zero jitter, controllable pulse width, pulse charging system to rapidly deliver energy to PCSS RF amplifier modules. For example, a Marx generator circuit configuration or other triggerable capacitor bank circuit can be employed, where spark gaps or conventional semiconductor switches would be replaced by GaN:C BOSS devices. Light generated from a single master laser system can be used to control both the triggering of the pulsed power circuit as well as actuating the PCSS switches within the RF amplifier modules without jitter. A standard Nd: YAG laser could be used were the first harmonic (1064 nm) capable of quenching the GaN:C BOSS device to turn off the charging pulse. Upconverted light could be used to drive the PCSS and turn on the GaN:C BOSS switch simultaneously. The timing of the switch quenching and pulse width control could be varied using optical delay approaches. GaN:C BOSS devices used as switches in each stage in a multi-stage Marx generator could enable simultaneous stage triggering, variable or selectable stage control (e.g., selectively turning off some of the stages of the Marx by shuttering light), higher repetition rate operation since the quenchable aspect allows for fast turn off of the devices to enable quicker recharge of the capacitors, as well increased reliability, device longevity, and a fully solid state approach avoiding EPA-restricted gases or even compressed air for recharge, all of which are shortcomings of spark gaps.

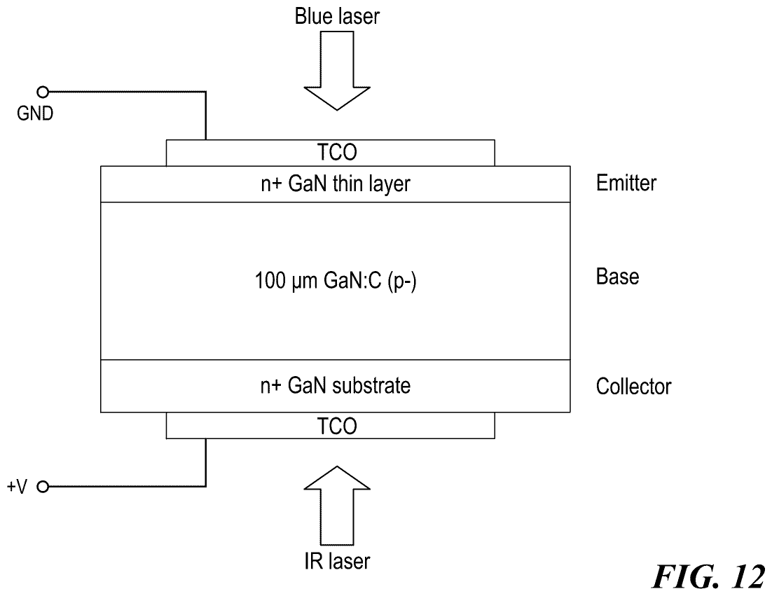

Embodiments of the disclosed technology enable the carbon-doped GaN to be used in implementing a high-gain optical bipolar junction transistor (OBJT), an example of which is illustrated in FIG. 12. In these embodiments, carbon in a substitutional nitrogen site, C_{N} is a deep acceptor in GaN, whose energy level is located at ˜0.9 eV above the valence band. At a carbon concentration of 2×10¹⁸ cm⁻³, the free hole concentration is ˜3×10⁶ cm⁻³ at room temperature, and the GaN:C layer behaves as a weak p-type layer.

As shown in FIG. 12, starting with a hydride vapor-phase epitaxy (HVPE)-grown carbon-doped GaN (GaN:C) layer with a nominal thickness of 100 μm and a nominal dopant concentration [C] of ˜2× 10¹⁸ cm⁻³ on an n+ GaN substrate, a thin layer of GaN with nominal thickness of 1 μm and 1×10¹⁹ cm⁻³ of n-type doping is epitaxially grown on top of GaN:C layer. This results in an optical BJT (OBJT) with the n+ GaN thin layer as the emitter, GaN:C as the p-base, and n+ substrate as the collector.

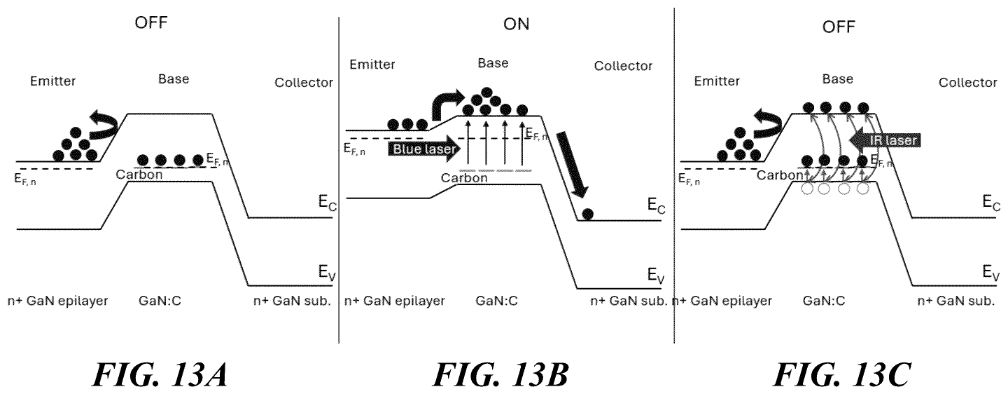

When in operation, the emitter is connected to ground, and the collector is biased at a high positive voltage. The base/collector junction is reverse-biased, so there is no current flowing therethrough. As shown in FIG. 13A, the free electrons in the base layer are trapped in carbon sites which makes this layer resistive. The free electrons in the emitter are blocked from being injected into the base by the potential barrier at the interface of the emitter and the base, and the device is in the OFF state.

When the device is illuminated with a blue laser (380 nm) through a transparent electrode (e.g., a transparent conductive oxide (TCO)) on top of emitter, the electrons trapped at carbon sites are photo-excited to the conduction band. Generated free electrons shift the electron fermi level in base region upward and reduce the barrier height between emitter and base. The electrons from the emitter inject into the base and transport to the depletion boundary at base/collector junction. Then electrons are swept to the collector by electric field, and the device is turned to the ON state (as shown in FIG. 13B).

To turn the device back to the OFF state, the blue laser is shut off, and an infrared (IR) laser (1064 nm) is turned on. The IR laser facilitates speeding up the turn-off transient. As shown in FIG. 13C, the IR laser excites electrons from the valence band to the carbon sites, and leaves free holes in the valence band. The free holes quickly recombine with free electrons (in nanoseconds) via radiative recombination or nonradiative recombination through mid-level defects. As the amount of electrons decreases, the electron Fermi level in base region shifts downward, and increases the potential barrier between emitter and base. The electron injection process is stopped, and the device is turned to the OFF state.

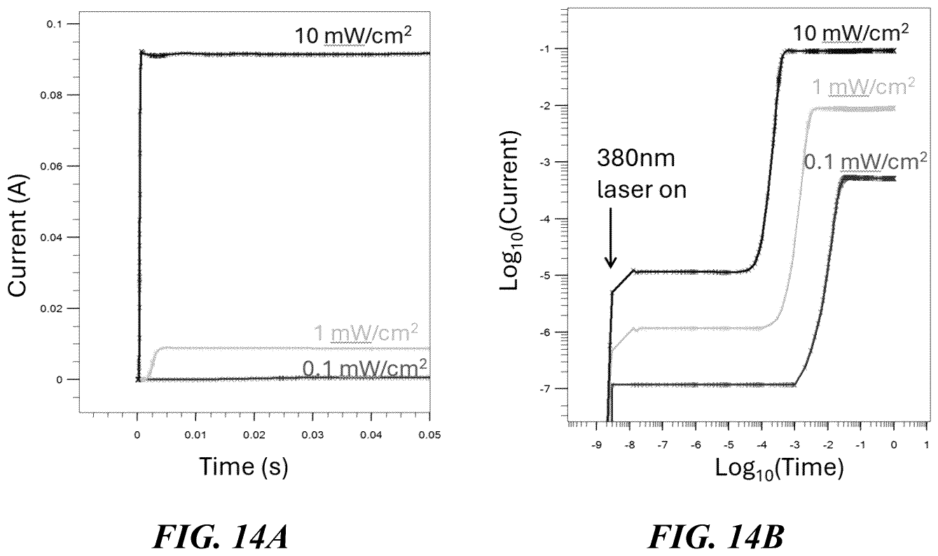

Numerical simulations of the transient photocurrent output from the GaN:C oBJT were performed. In simulations, the device has a size of 2.6 mm in diameter (or with an area of 0.053 cm²) and the voltage applied is 1 kV. FIG. 14A shows the photocurrent is proportional to the laser power. A super high photo-responsivity of 175 A/W is achieved at a power level of 10 mW/cm². As a comparison, a GaN PCSS biased to 24.5 kV/cm achieved 3.5×10⁻⁵ A/W at 532 nm and 12 mJ/pulse in an existing implementation, which is 6 orders of magnitude lower than the described embodiment. Herein, the gain of oBJT is defined by the steady-state output photocurrent from the oBJT with a certain level of input optical power, divided by the required current to generate such an optical power in an ideal diode assuming all injected carriers are converted to photons without any energy loss. An ideal photodetector has a gain of unity without amplification effect. The calculated gain of the oBJT is 583 at 10 mW/cm². The high gain value results from the current amplifying effect due to electron injection from the emitter. FIG. 14B plots the transient photocurrent and time, both in logarithm scale. At time of 3 ns, the blue laser is turned on. The p base is populated with free electrons, and a low level photocurrent flows instantaneously. It takes time for injected electrons to transport to the high-field region, which is located close to the base/collector junction, when the current starts to rise quickly and reaches its steady state. In some embodiments, a higher laser power can effectively reduce the rise time. For example, increasing the power level from 0.1 to 10 mW/cm² results in the rise time being reduced from 42 ms to 0.6 ms. This suggests that a higher laser power is required in order to operate the device at a higher repetition rate. Other parameters that can be tuned to achieve a higher repetition rate include reducing GaN:C layer thickness and lower carbon concentration in the base region, but at a risk of lowering blocking voltage.

The oBJT performance of steady-state current, rise time, responsivity, and gain at different laser power levels are summarized in Table 3 shown below. Therein, the rise time is dominated by the travel time of the injected electron from the emitter to the depletion boundary in the base region, and the gain is defined as the output photocurrent divided by the current required to generate the optical power in an ideal laser diode.

TABLE 3
Responsivities and rise times for different laser power levels

| Laser power | Steady-state | Rise time | Responsivity | |
|---|---|---|---|---|
| (mW/cm²) | current (mA) | (ms) | (A/W) | Gain |
| 10 | 93 | 0.6 | 175 | 583 |
| 1 | 9.0 | 4.8 | 170 | 566 |
| 0.1 | 0.5 | 42 | 94 | 313 |

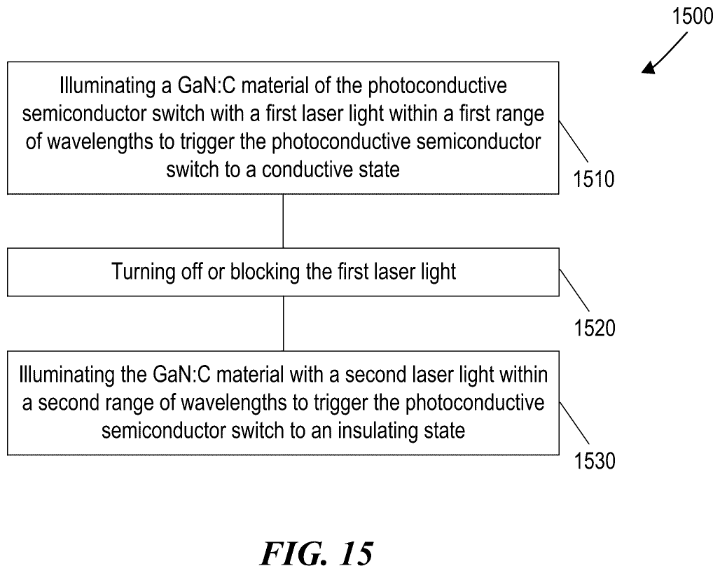

FIG. 15 illustrates a flowchart of a method 1500 for operating a photoconductive semiconductor switch. Method 1500 includes, at operation 1510, illuminating a carbon-doped gallium nitride (GaN:C) material of the photoconductive semiconductor switch with a first laser light within a first range of wavelengths to trigger the photoconductive semiconductor switch to a conductive state. In this example method, the first range of wavelengths comprises an ultraviolet (UV) or a blue wavelength range.

Method 1500 includes, at operation 1520, turning off or blocking the first laser light.

Method 1500 includes, at operation 1530, illuminating the GaN:C material with a second laser light within a second range of wavelengths to trigger the photoconductive semiconductor switch to an insulating state. In this example method, switching from the conductive state to the insulating state occurs within a sub-nanosecond range, and the second range of wavelengths includes an infrared (IR) or a red wavelength range. Furthermore, the photoconductive semiconductor switch operable to remain in the insulating state for one or more seconds as long as the GaN:C material is not illuminated with the first laser light.

In some embodiments, the first laser light is produced by a laser source operating in a continuous wave (CW) mode or a pulsed mode, and the second laser light is produced by a laser source operating in a pulsed mode.

In some embodiments, the first range of wavelengths spans 370 nm to 410 nm and the second range of wavelengths spans 1000 nm to 1200 nm. In some examples, the first laser light has a center wavelength of 380 nm and the second laser light has a center wavelength of 1064 nm.

In some embodiments, a dopant concentration of the carbon-doped gallium nitride material ranges from 1×10¹⁶ cm⁻³ to 1×10²⁰ cm⁻³.

In some embodiments, and upon being triggered to the conductive state, the photoconductive semiconductor switch is operable to remain in the conductive state for multiple milliseconds as long as the carbon-doped gallium nitride material is not illuminated with the second laser light.

In some embodiments, a resistivity of the carbon-doped gallium nitride material in the insulating state is greater than 1×10¹³ ohm-cm (Ω·cm).

In some embodiments, and with reference to FIG. 7, triggering the photoconductive semiconductor switch to the conductive state comprises using the first laser light to excite electrons in the carbon-doped gallium nitride material to a conduction band thereof, and triggering the photoconductive semiconductor switch to the insulating state comprises using the second laser light to excite holes to or the electrons from a valence band to a carbon site, thereby resulting in a recombination of the electrons and the holes, such that the photoconductive semiconductor switch remains in the insulating state due a lack of sufficient free electrons in the conduction band and capture of excess holes back to the carbon site.

In some embodiments, method 1500 includes the operation of passing the first laser light through a conversion layer, prior to the first laser light illuminating the carbon-doped gallium nitride material, to convert a wavelength of the first laser light from an initial wavelength to a wavelength within the first range of wavelengths. Herein, the initial wavelength is less than a minimum wavelength of the first range of wavelengths. In some examples, the conversion layer comprises at least one of a bulk epitaxial semiconductor, an epitaxial semiconductor composed of quantum wells, an epitaxial semiconductor composed of quantum dots, an epitaxial semiconductor composed with a fluorescent dopant, or a luminescent layer.

Embodiments of the disclosed technology are directed to GaN:C-based device that is operable as a photoconductive semiconductor switch, an opening switch, and/or an optical bipolar junction transistor (BJT). In an example, the GaN:C-based device includes one or more electrodes configured to receive one or more voltages, and a region comprising a GaN:C material that is configured to (a) receive a first laser light within a first range of wavelengths comprising a UV wavelength or a blue wavelength to trigger the device to a conductive state, and (b) receive a second laser light within a second range of wavelengths comprising an IR wavelength or a red wavelength, while the first laser light is turned off or otherwise blocked, to trigger the device to an insulating state.

In some embodiments, a thickness of the GaN:C material is nominally 100 μm, and wherein a dopant concentration of the GaN:C material ranges from 1×10¹⁶ cm⁻³ to 1×1020 cm⁻³.

In some embodiments, the first range of wavelengths spans 370 nm to 410 nm and the second range of wavelengths spans 1000 nm to 1200 nm. In some examples, the first laser light has a 380 nm center wavelength and the second laser light has a 1064 nm center wavelength.

In some embodiments, the device is operable as a photoconductive semiconductor switch implemented in each stage of a multi-stage Marx generator that is configured to generate a high-voltage pulse from a low-voltage direct current (DC) supply.

In some embodiments, the device is operable as a bulk optical semiconductor switch (BOSS).

In some embodiments, and with reference to FIG. 4, the device is operable as a photoconductive semiconductor switch. Herein, the one or more electrodes include an anode and a cathode, and the photoconductive semiconductor switch is configured to receive the first laser light from a pulsed laser source in response to the pulsed laser source receiving one or more signals from a laser controller circuit. Herein, the photoconductive semiconductor switch includes a p+ type GaN material and an n type GaN material that are positioned with respect to the GaN:C material such that the first laser light and the second laser light pass through the p+ type GaN material, then through the n type GaN material before reaching the GaN:C material from a first side of the GaN:C material, and further includes an n+ type GaN substrate positioned on a second side of the GaN:C material. In some examples, a thickness of the p+ type GaN material is less than (a) a thickness of the n type GaN material, (b) a thickness of the GaN:C material, and (c) a thickness of the n+ type GaN substrate. In other examples, the GaN:C material being triggered to the conductive state causes a junction between the p+ type GaN material and the n type GaN material to become reverse biased, and the GaN:C material being triggered to the insulating state causes a junction between the n type GaN material and the GaN:C material to become forward biased.

In some embodiments, and with reference with FIG. 5, the device is operable as a photoconductive semiconductor switch that is configured to include a first laser source and a second laser source integrated therein to produce the first laser light and the second laser light, respectively, each laser source is positioned above the GaN:C material, and each laser source comprises a multiple quantum well (MQW) structure. In some examples, the first laser source includes a p+ type GaN material and an n type GaN material that are positioned with respect to the GaN:C material and the MQW structure such that an incident light passes through the p+ type GaN material, then through the MQW structure, and then through the n type GaN material before reaching the GaN:C material from a first side of the GaN:C material, and further includes an n+ type GaN substrate positioned on a second side of the GaN:C material. In these examples, the MQW structure comprises alternating layers of a GaN material and an indium gallium nitride (InGaN) material. In other examples, the second laser source includes a p+ type GaN material and an n type GaN material that are positioned with respect to the GaN:C material and the MQW structure such that an incident light passes through the n type GaN material, then through the MQW structure, and then through the p+ type GaN material before reaching the GaN:C material from a first side of the GaN:C material, and further includes an n+ type GaN substrate positioned on a second side of the GaN:C material. In these examples, the MQW structure comprises alternating layers of a GaN material and either (a) InGaN or (b) an erbium (Er)-doped indium gallium nitride (InGaN: Er) material.

In some embodiments, and with reference to FIGS. 6A-6C, the device is implemented in parallel with a load. In this configuration, the device is operable as an opening switch. In the conductive state, the device is configured to shunt a closely coupled capacitance, and in the insulating state, the device enables a value of an output voltage of the opening switch to be proportional to a rate of change of a current through the load.

In some embodiments, and with reference to FIG. 12, the device is operable as an optical bipolar junction transistor (BJT) and the one or more electrodes include a first transparent electrode and a second transparent electrode. In this embodiment, the device further includes an n+ type gallium nitride (GaN) material and an n+ type GaN substrate. Herein, (a) the first transparent electrode and the n+ type GaN material are positioned with respect to the GaN:C material such that the first laser light passes through the first transparent electrode, then through the n+ type GaN material before reaching the GaN:C material from a first side of the GaN:C material, and (b) the second transparent electrode and the n+ type GaN substrate are positioned with respect to the GaN:C material such that the second laser light passes through the second transparent electrode, then through the n+ type GaN substrate before reaching the GaN:C material from a second side of the GaN:C material.

In some embodiments, the n+ type GaN material, the region comprising the GaN:C material, and the n+ type GaN substrate are configured to operate as an emitter, a base, and a collector of the optical bipolar junction transistor, respectively.

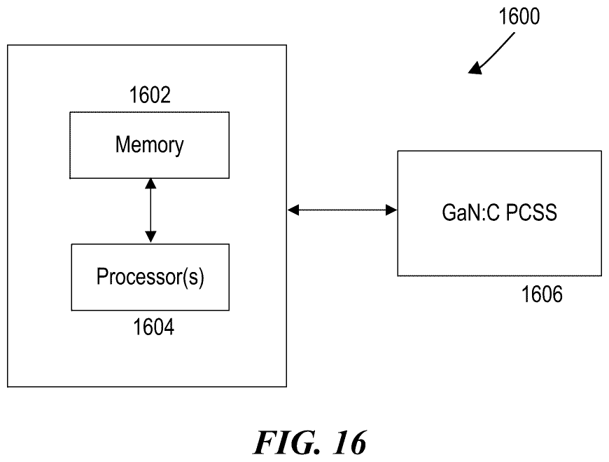

FIG. 16 is a notional block diagram of an example hardware apparatus that can accommodate at least some of the disclosed technology. The hardware apparatus 1600 may be implemented in a fixed or mobile framework to enable operating the GaN:C PCSS in both the laboratory and in the field. The apparatus 1600 may include one or more processors 1602, one or more memories 1604 and a GaN:C PCSS 1606. The processor(s) 1602 may be configured to implement one or more methods (including, but not limited to, method 1500) described in the present document. The memory (memories) 1604 may be used for storing data and code used for implementing the methods and techniques described herein. The GaN:C PCSS 1606 is coupled to the processor 1602 and/or the memory 1604 and can receive commands and signals from the processor; the GaN:C PCSS 1606 may also transmit signals including data and commands to the processor 1602 and/or memory 1604.

Implementations of the subject matter and the functional operations described in this patent document can be implemented in various systems, optical components, digital electronic circuitry, or in computer software, firmware, or hardware, including the structures disclosed in this specification and their structural equivalents, or in combinations of one or more of them.

Part of the disclosed subject matter in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of nonvolatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A method of operating a photoconductive semiconductor switch, comprising:
illuminating a carbon-doped gallium nitride material of the photoconductive semiconductor switch with a first laser light within a first range of wavelengths to trigger the photoconductive semiconductor switch to a conductive state, wherein the first range of wavelengths comprises an ultraviolet (UV) or a blue wavelength range;
turning off or blocking the first laser light; and
illuminating the carbon-doped gallium nitride material with a second laser light within a second range of wavelengths to trigger the photoconductive semiconductor switch to an insulating state, wherein switching from the conductive state to the insulating state occurs within a sub-nanosecond range, the second range of wavelengths comprising an infrared (IR) or a red wavelength range, and the photoconductive semiconductor switch operable to remain in the insulating state for one or more seconds as long as the carbon-doped gallium nitride material is not illuminated with the first laser light.

2. The method of claim 1, wherein the first laser light is produced by a laser source operating in a continuous wave (CW) mode or a pulsed mode, and wherein the second laser light is produced by a laser source operating in a pulsed mode.

3. The method of claim 1, wherein the first range of wavelengths spans 370 nm to 410 nm and the second range of wavelengths spans 1000 nm to 1200 nm.

4. The method of claim 3, wherein the first laser light has a center wavelength of 380 nm and the second laser light has a center wavelength of 1064 nm.

5. The method of claim 1, wherein a dopant concentration of the carbon-doped gallium nitride material ranges from 1×10¹⁶ cm⁻³ to 1×10²⁰ cm⁻³.

6. The method of claim 1, wherein, upon being triggered to the conductive state, the photoconductive semiconductor switch is operable to remain in the conductive state for multiple milliseconds as long as the carbon-doped gallium nitride material is not illuminated with the second laser light.

7. The method of claim 1, wherein a resistivity of the carbon-doped gallium nitride material in the insulating state is greater than 1×10¹³ ohm-cm (Ω·cm).

8. The method of claim 1, wherein:
triggering the photoconductive semiconductor switch to the conductive state comprises using the first laser light to excite electrons in the carbon-doped gallium nitride material to a conduction band thereof;
triggering the photoconductive semiconductor switch to the insulating state comprises using the second laser light to excite holes to or the electrons from a valence band to a carbon site, thereby resulting in a recombination of the electrons and the holes, such that the photoconductive semiconductor switch remains in the insulating state due a lack of sufficient free electrons in the conduction band and capture of excess holes back to the carbon site.

9. The method of claim 1, comprising:
passing the first laser light through a conversion layer, prior to the first laser light illuminating the carbon-doped gallium nitride material, to convert a wavelength of the first laser light from an initial wavelength to a wavelength within the first range of wavelengths,
wherein the conversion layer comprises at least one of:
a bulk epitaxial semiconductor;
an epitaxial semiconductor composed of quantum wells;
an epitaxial semiconductor composed of quantum dots;
an epitaxial semiconductor composed with a fluorescent dopant; or
a luminescent layer, and
wherein the initial wavelength is less than a minimum wavelength of the first range of wavelengths.

10. A device, comprising:
one or more electrodes configured to receive one or more voltages; and
a region comprising a carbon-doped gallium nitride (GaN:C) material configured to:
receive a first laser light within a first range of wavelengths comprising an ultraviolet (UV) wavelength or a blue wavelength to trigger the device to a conductive state, and
receive a second laser light within a second range of wavelengths comprising an infrared (IR) wavelength or a red wavelength, while the first laser light is turned off or otherwise blocked, to trigger the device to an insulating state.

11. The device of claim 10, wherein a thickness of the GaN:C material is nominally 100 μm, and wherein a dopant concentration of the GaN:C material ranges from 1×10¹⁶ cm⁻³ to 1×10²⁰ cm⁻³.

12. The device of claim 10, wherein the first range of wavelengths spans 370 nm to 410 nm and the second range of wavelengths spans 1000 nm to 1200 nm.

13. The device of claim 12, wherein the first laser light has a nominal wavelength of 380 nm and the second laser light has a nominal wavelength of 1064 nm.

14. The device of claim 10, wherein the device is operable as a photoconductive semiconductor switch implemented in each stage of a multi-stage Marx generator that is configured to generate a high-voltage pulse from a low-voltage direct current (DC) supply.

15. The device of claim 10, wherein the device is operable as a bulk optical semiconductor switch (BOSS).

16. The device of claim 10, wherein the device is operable as a photoconductive semiconductor switch, wherein the one or more electrodes include an anode and a cathode, and wherein the photoconductive semiconductor switch is configured to receive the first laser light from a pulsed laser source in response to the pulsed laser source receiving one or more signals from a laser controller circuit.

17. The device of claim 16, comprising:
a p+ type GaN material;
an n type GaN material,
wherein the p+ type GaN material and the n type GaN material are positioned with respect to the GaN:C material such that the first laser light and the second laser light pass through the p+ type GaN material, then through the n type GaN material before reaching the GaN:C material from a first side of the GaN:C material; and
an n+ type GaN substrate positioned on a second side of the GaN:C material.

18. The device of claim 17, wherein a thickness of the p+ type GaN material is less than (a) a thickness of the n type GaN material, (b) a thickness of the GaN:C material, and (c) a thickness of the n+ type GaN substrate.

19. The device of claim 17, wherein:
the GaN:C material being triggered to the conductive state causes a junction between the p+ type GaN material and the n type GaN material to become reverse biased, and
the GaN:C material being triggered to the insulating state causes a junction between the n type GaN material and the GaN:C material to become forward biased.

20. The device of claim 10, wherein:
the device is operable as a photoconductive semiconductor switch,
the photoconductive semiconductor switch is configured to include a first laser source and a second laser source integrated therein to produce the first laser light and the second laser light, respectively,
each laser source is positioned above the GaN:C material, and
each laser source comprises a multiple quantum well (MQW) structure.

21. The device of claim 20, wherein the first laser source comprises:
a p+ type GaN material;
an n type GaN material,
wherein the p+ type GaN material and the n type GaN material are positioned with respect to the GaN:C material and the MQW structure such that an incident light passes through the p+ type GaN material, then through the MQW structure, and then through the n type GaN material before reaching the GaN:C material from a first side of the GaN:C material; and
an n+ type GaN substrate positioned on a second side of the GaN:C material.

22. The device of claim 21, wherein the MQW structure comprises alternating layers of a GaN material and an indium gallium nitride (InGaN) material.

23. The device of claim 20, wherein the second laser source comprises:
a p+ type GaN material;
an n type GaN material,
wherein the p+ type GaN material and the n type GaN material are positioned with respect to the GaN:C material and the MQW structure such that an incident light passes through the n type GaN material, then through the MQW structure, and then through the p+ type GaN material before reaching the GaN:C material from a first side of the GaN:C material; and
an n+ type GaN substrate positioned on a second side of the GaN:C material.

24. The device of claim 23, wherein the MQW structure comprises alternating layers of a GaN material and either (a) InGaN or (b) an erbium (Er)-doped indium gallium nitride (InGaN: Er) material.

25. The device of claim 10, wherein the device is implemented in parallel with a load, and wherein the device:
is operable as an opening switch;
in the conductive state, is configured to shunt a closely coupled capacitance; and
in the insulating state, enables a value of an output voltage of the opening switch to be proportional to a rate of change of a current through the load.

26. The device of claim 10, wherein the device is operable as an optical bipolar junction transistor, wherein the one or more electrodes include a first transparent electrode and a second transparent electrode, and wherein the device comprises:
an n+ type gallium nitride (GaN) material,
wherein the first transparent electrode and the n+ type GaN material are positioned with respect to the GaN:C material such that the first laser light passes through the first transparent electrode, then through the n+ type GaN material before reaching the GaN:C material from a first side of the GaN:C material; and
an n+ type GaN substrate,
wherein the second transparent electrode and the n+ type GaN substrate are positioned with respect to the GaN:C material such that the second laser light passes through the second transparent electrode, then through the n+ type GaN substrate before reaching the GaN:C material from a second side of the GaN:C material, and
wherein the n+ type GaN material, the region comprising the GaN:C material, and the n+ type GaN substrate are configured to operate as an emitter, a base, and a collector of the optical bipolar junction transistor, respectively.

27. The device of claim 26, wherein a thickness of the n+ type GaN material is nominally 1 μm and a concentration of n-type doping is nominally 1×10¹⁹ cm⁻³.

28. The device of claim 26, wherein a thickness of the GaN:C material is nominally 100 μm, and wherein a dopant concentration of the GaN:C material ranges from 1×10¹⁶ cm⁻³ to 1×10²⁰ cm⁻³.
